(19) United States
(12) Patent Application Publication
(10) Pub. No.: US 2016/0093661 A1
(43) Pub. Date: Mar. 31, 2016

(54) IMAGE SENSOR HAVING AN EMBEDDED COLOR FILTER AND ITS PREPARATION METHOD

(71) Applicant: Wuhan Xinxin Semiconductor Manufacturing Co., Ltd, Wuhan (CN)

(72) Inventors: Siping Hu, Wuhan (CN); Jifeng Zhu, Wuhan (CN); Sheng'an Xiao, Wuhan (CN); Jinwen Dong, Wuhan (CN)

(21) Appl. No.: 14/813,115

(22) Filed: Jul. 29, 2015

(30) Foreign Application Priority Data
Sep. 30, 2014 (CN) 201410526222.7

(51) Int. Cl. H01L 27/146

(52) U.S. Cl. CPC H01L 27/14645; H01L 27/14621; H01L 27/14632; H01L 27/14636; H01L 27/14634; H01L 27/14685; H01L 27/14689; H01L 27/14612; H01L 27/1469

(57) ABSTRACT

The invention relates to the field of semiconductor manufacturing process, more particularly, to an image sensor having an embedded color filter and its preparation method, providing a bonded wafer with leads, and performing preparation process of metal insulated gates and embedding process of color filters on bonded wafers, etching to expose the opening of the lead, and eventually combining color filter process with lead process; the implementation of the invention is simple, implementation difficulty is relatively small, and can greatly improve the transmission speed of output image signal and image quality, at the same time, the technical scheme can be used in front-illuminated, back-illuminated and stackable image sensors, etc.

### BACKGROUND OF THE INVENTION

1. Field of the Invention

The invention relates to the field of semiconductor manufacturing process, more particularly, to an image sensor having an embedded color filter and its preparation method.

2. Description of the Related Art

With the unceasing mature development of semiconductor manufacturing technology, in the process of semiconductor preparation, usually generates complex integrated circuit graphics on wafers, and encapsulates to form the device can be used directly, the encapsulation in addition to guard the wafers using the shell, more important is to form leads can be connected with other components.

Such as the embedded color filter on the surface of the wafer, the main is to make color filter in metal insulated gate, so that to reduce the distance light arrives at the device through the color filter and filter film, and achieve the improvement of image quality and noise reduction.

As shown in FIG. 1 is the structure of the combination of an embedded color filter process and lead process, specifically comprising: substrate 10, filter film 101, metal insulated gate 102, color filter 103, bonding pad 104 and leads 105; However, the implementation plan of the structure is complex, the difficulty of the implementation is relatively large and the image quality is low, which will bring bad influence on the performance of semiconductor devices.

But now the process of combining an embedded color filter with the lead has no other details in the field of the semiconductor technology, so a new process of the combination of lead and an embedded color filter has increasingly become the research direction of those skilled in the field.

### SUMMARY OF THE INVENTION

In view of the above problems, the invention provides an image sensor having an embedded color filter and its preparation method, to solve the defects of complex implementation, relatively large implementation difficulty and the impact on device performance of the process of combining an embedded color filter with the lead in the current technology.

The technical scheme the invention adopted to solve the above technical problems is:

An image sensor having an embedded color filter, comprising:

A bonded wafer, said bonded wafer include first wafer and second wafer bonded above the first wafer;

a groove provided at top of said second wafer, a lead having an opening on its top being provided in the groove;

a second dielectric layer covering an upper surface of the second wafer and the lead excluding the opening, said second dielectric layer filling said groove.

The upper surface of said second dielectric layer apart from the top of the groove is provided with a number of equidistant metal insulated gates;

A color filter is arranged between each two adjacent metal insulated gates, and tops of the color filters are flush with those of the metal insulated gates.

Preferably, the image sensor as described above, wherein said first wafer includes a first substrate and a first BEOL dielectric layer, said second wafer includes a second substrate and a second BEOL dielectric layer;

said first BEOL dielectric layer covers an upper surface of the first substrate, said second BEOL dielectric layer covers an upper surface of said first BEOL dielectric layer, and said second substrate covers an upper surface of said second BEOL dielectric layer;

wherein, said groove is arranged in said second substrate of said second wafer, and said groove exposes parts of the upper surface of said second BEOL dielectric layer;

Preferably, the image sensor as described above, wherein the upper surface of said second wafer is also covered with a first dielectric layer, and said first dielectric layer locates between said second wafer and said second dielectric layer.

Preferably, the image sensor as described above, wherein a first metal layer are arranged in said first BEOL dielectric layer and said second BEOL dielectric layer respectively, and the two first metal layers contact with each other accurately;

wherein, said second BEOL dielectric layer is also provided with a second metal layer, and said second metal layer connects to said lead.

A preparation method of image sensor having an embedded color filter, comprising:

Step S1: proving a bonded wafer, said bonded wafer including a first wafer and a second wafer bonded above the first wafer; a groove being provided at top of said second wafer, and a lead having an opening on its top being provided in the groove;

Step S2: depositing a second dielectric layer to cover said second wafer and said lead and to fill said groove;

Step S3: performing a planarization process to said second dielectric layer, and then preparing a number of equidistant metal insulated gates on an upper surface of said second dielectric layer apart from top of the groove;

Step S4: embedding a color filter between each two adjacent metal insulated gates, and tops of the color filters being flush with those of the metal insulated gates, then removing parts of said second dielectric layer to expose the opening at the top of the lead.

Preferably, the method as described above, wherein said first wafer includes a first substrate and a first BEOL dielectric layer, and said second wafer includes a second substrate and a second BEOL dielectric layer;

said first BEOL dielectric layer covers an upper surface of the first substrate, said second BEOL dielectric layer covers an upper surface of said first BEOL dielectric layer, and said second substrate covers an upper surface of said second BEOL dielectric layer;

wherein, said groove is arranged in said second substrate of said second wafer, and said groove exposes parts of the upper surface of said second BEOL dielectric layer.

Preferably, the method as described above, wherein a first metal layer is provided in said first BEOL dielectric layer and said second BEOL dielectric layer respectively, and the two first metal layers contact with each other accurately;

wherein, said second BEOL dielectric layer is also provided with a second metal layer, and said second metal layer connects to said lead.

Preferably, the method as described above, wherein in step S2, a first dielectric layer is provided between said second wafer and said second dielectric layer;

said first dielectric layer covers the upper surface of said second wafer and a bottom and side walls of the groove.

Preferably, the method as described above, wherein material of said second dielectric layer is silicon oxide.

The above technical scheme has the following advantages or beneficial effects:

The invention discloses an image sensor having an embedded color filter and its preparation method, providing a bonded wafer with leads, and carrying out preparation process of metal insulated gates and landfill process of color filters on the bonded wafer, etching to expose the opening of the lead, and eventually combining color filter process with lead process; the implementation of the invention is simple, implementation difficulty is relatively small, and can greatly improve the transmission speed of output image signal and image quality, at the same time, the technical scheme can be used in front-illuminated, back-illuminated and stackable image sensors, etc.

### BRIEF DESCRIPTIONS OF THE DRAWINGS

By reading reference to the following detailed descriptions of the drawings to non-limiting embodiment, the invention and its features, shapes and advantages will become more apparent. The same numerals indicate the same parts throughout the drawings. The drawings have not drawn to scale, the emphasis is showing the spirit of the invention.

FIG. 1 is a structural representation of combination of color filter and lead in the current technology;

FIG. 2 is a structural representation of image sensor having an embedded color filter of the invention;

FIGS. 3 to 7 are flow charts of preparation method of image sensor having an embedded color filter of the invention.

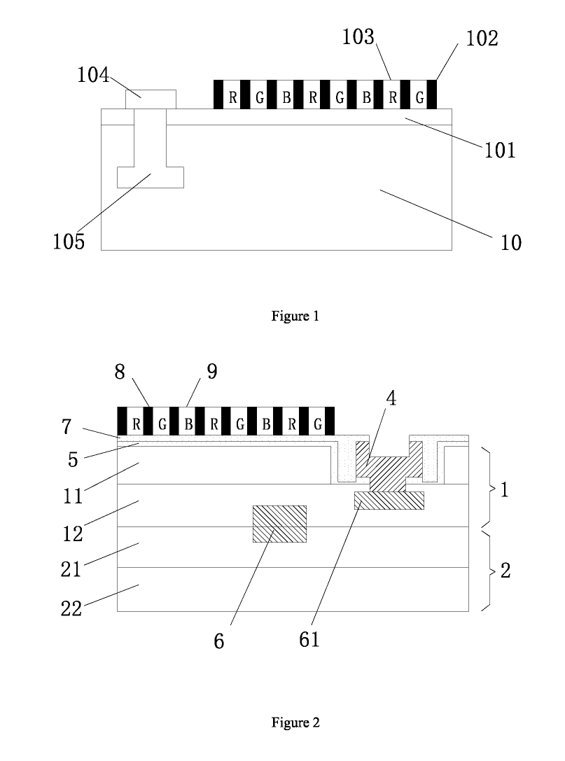

### DETAILED DESCRIPTIONS

The following combines with the appended drawings and embodiments to further describe the invention, but not as the limit of the invention.

An image sensor having an embedded color filter as referred in the embodiments of the invention, as shown in FIG. 2, the image sensor comprises:

The first BEOL dielectric layer 21 covers an upper surface of the first substrate 22, the second BEOL dielectric layer 12 covers an upper surface of the first BEOL dielectric layer 21, the second substrate 11 covers an upper surface of the second BEOL dielectric layer 12, the first BEOL dielectric layer 21 and second BEOL dielectric layer 12 are all provided with a first metal layer 6, and the two first metal layers 6 contact with each other accurately.

The image sensor is also provided with a groove structure, the groove structure is arranged in the second wafer 1, specifically the groove locates in the second substrate 11 of the second wafer 1 and completely exposes an upper surface of the second BEOL dielectric layer 12, in the embodiments of the invention, the groove is also provided with a lead 4 having an opening on its top, the lead 4 extends to the second BEOL dielectric layer 12.

Wherein the second BEOL dielectric layer 12 is also provided with a second metal layer 61, the second metal layer 61 is used to connect to the above lead 4.

In the embodiments of the invention, an upper surface of the second wafer 1 is covered with a first dielectric layer 5, the first dielectric layer 5 partially covers a bottom and side walls of the groove, and the first dielectric layer 5 is also arranged between the lead 4 and the bottom of the groove to achieve isolation. In addition, an upper surface of the first dielectric layer 5 apart from the top of the groove is also covered with a second dielectric layer 7, meanwhile the second dielectric layer 7 fills the above groove.

As a preferred embodiment, the material of the above second dielectric layer 7 is silicon oxide, and the silicon oxide is just a better embodiment, it can also use other conventional materials in semiconductor preparation technology to cover the first dielectric layer 5 and to fill the above groove in other embodiments.

The image sensor also comprises a number of metal insulated gates 8 located on the part of upper surface of the second dielectric layer 7 apart from the second dielectric layer 7 on the top of the groove; the metal insulated gates 8 equidistantly distribute, a color filter 9 (for example including RGB trichromatic filters) is arranged between each two adjacent metal insulated gates, preferably, tops of the color filters 9 are flush with those of the metal insulated gates 8.

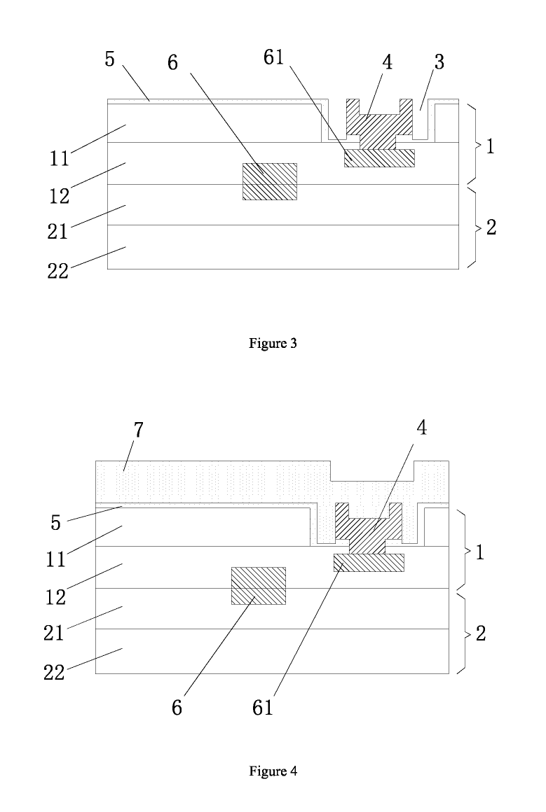

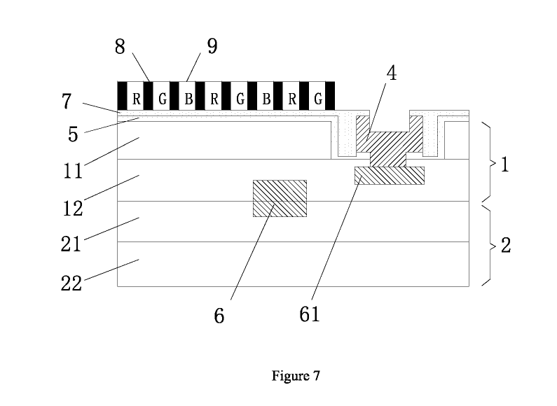

In addition the invention also involves a preparation method of image sensor having an embedded color filter, as shown in FIG. 3˜FIG. 7:

Step S1: proving a bonded wafer, the bonded wafer including a first wafer 2 and a second wafer 1 bonded above the first wafer 2; wherein the first wafer 2 includes a first substrate 22 and a first BEOL dielectric layer 21, the second wafer 1 includes a second substrate 11 and a second BEOL dielectric layer 12.

During the traditional preparation of the bonded wafers, firstly prepares the first BEOL dielectric layer 21 on one surface of the first substrate 22, and prepares the second BEOL dielectric layer 12 on one surface of the second substrate 11, farther bond the first BEOL dielectric layer 21 and the second BEOL dielectric layer 12. In FIG. 3, the first BEOL dielectric layer 21 covers an upper surface of the first substrate 22, the second BEOL dielectric layer 12 locates above the first BEOL dielectric layer 21, the second substrate 11 covers an upper surface of the second BEOL dielectric layer 12. In addition, the first BEOL dielectric layer 21 and the second BEOL dielectric layer 12 are all provided with a first metal layer 6, and the two first metal layers 6 contact with each other accurately, as shown in FIG. 3;

The top of the bonded wafers is also provided with a groove 3, the groove 3 is arranged in the second wafer 1, specifically the groove 3 locates in the second substrate 11 of the second wafer 1 and completely exposes the upper surface of the second BEOL dielectric layer 12, in the embodiments of the invention, and a lead 4 having an opening on its top being provided in the groove, the lead 4 extends to the second BEOL dielectric layer 12.

Wherein the second BEOL dielectric layer 12 is also embedded arranged with a second metal layer 61, the second metal layer 61 connects to the above lead 4.

In an optional but not restrictive embodiment, there needs to carry out thinning process on the bonded wafers in order to thin the second wafer 1 (it can be seen as to thin the second substrate 11 at the top of the second wafer 1).

Step S2: depositing a second dielectric layer 7 to cover the second wafer 1 and the lead 4 and to fill the above groove, as shown in FIG. 4; in the embodiments of the invention, the material of the above second dielectric layer 7 is silicon oxide, and the silicon oxide is just a better embodiment, it can also use other conventional materials in semiconductor preparation technology to realize the aim of the invention in other embodiments.

Wherein the upper surface of the bonded wafers is also covered with first dielectric layer 5, the first dielectric layer 5 is covered by second dielectric layer 7.

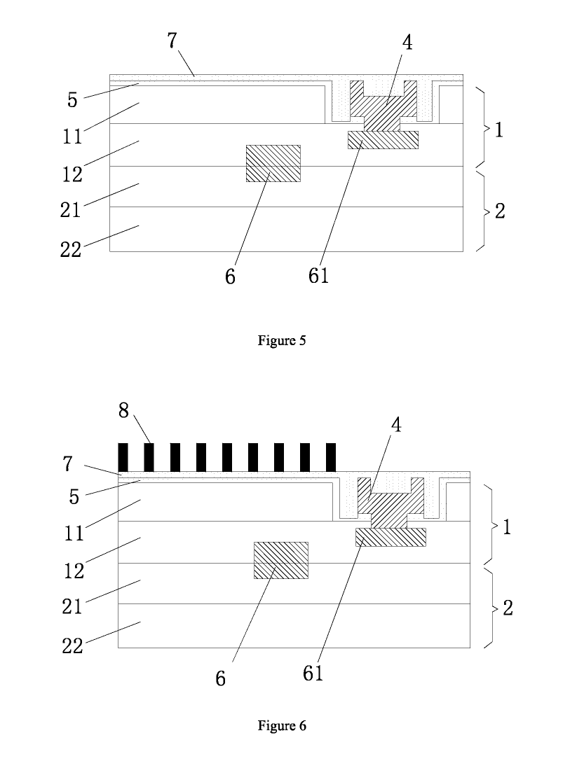

Step S3: performing a planarization process to the above second dielectric layer 7, in order to make the upper surface of the second dielectric layer 7 flush, as shown in FIG. 5; in an optional but not restrictive embodiment, it can use Chemical Mechanical Polishing to process on the second dielectric layer 7.

Continue to prepare a number of metal insulated gates 8 on the upper surface of the flattened second dielectric layer 7 apart from the top of the groove, the metal insulated gates 8 equidistant arrange, the intervals provide the environment for the subsequent filling of color filter 9, as shown in FIG. 6.

Step S4: performing embedding a color filter process, embedding a color filter 9 (for example including RGB trichromatic filters) between each two adjacent metal insulated gates 8, then etching part of the second dielectric layer 7 using photolithography and etching process to completely expose the opening of the lead 4, as shown in FIG. 7, and then performing the preparation of lead PAD (not shown in figure).

Wherein the above embedded color filter technology prepares the color filter 9 in the metal insulated gates 8, which can reduce the distance the light arrives to the device (such as photoelectric diode) through color filter 9, and prevent the optical crosstalk between the color filters 9 using the metal insulated gates 8, at the same time combine the color filter 9 with the lead 4 and greatly improve the transmission speed of the output image signal and imaging quality.

In summary, the invention discloses an image sensor having an embedded color filter and its preparation method, providing a bonded wafer with leads, and performing preparation process of metal insulated gates and embedding process of color filters on bonded wafers, etching to expose the opening of the lead, and eventually combining color filter process with lead process; the implementation of the invention is simple, implementation difficulty is relatively small, and can greatly improve the transmission speed of output image signal and image quality, at the same time, the technical scheme can be used in front-illuminated, back-illuminated and stackable image sensors, etc.

Those skilled in the art should be understood that those skilled in the art may implement the modified examples combining with the above-described embodiments, not repeat here. Examples of such changes do not affect the substance of the invention, not repeat here.

More than better implementation examples of the invention are described. To be understood that the invention is not limited to the specific embodiment in which the device and structure not described in detail should be understood be carried out in the normal way; anyone technical personnel familiar with the field may use the above-mentioned method and technical content to make many possible changes and modification, or change to the equivalent implementation under the condition of not out of the scope of the technical scheme of the invention, and this does not affect the substance of the invention. Therefore, any content without departing from the technical scheme of the invention, any simple modification, equivalent change and modify to the above examples based on the technology of the invention, are still belongs to the scope of the invention.

What is claimed is:

1. An image sensor having an embedded color filter, comprising:
a bonded wafer, said bonded wafer include first wafer and second wafer bonded above the first wafer;
a groove provided at top of said second wafer, a lead having an opening on its top being provided in the groove;
a second dielectric layer covering an upper surface of the second wafer and the lead excluding the opening, said second dielectric layer filling said groove.
the upper surface of said second dielectric layer apart from the top of the groove is provided with a number of equidistant metal insulated gates;
a color filter is arranged between each two adjacent metal insulated gates, and tops of the color filters are flush with those of the metal insulated gates.

2. The image sensor as claimed in claim 1, wherein said first wafer includes a first substrate and a first BEOL dielectric layer, said second wafer includes a second substrate and a second BEOL dielectric layer;
said first BEOL dielectric layer covers an upper surface of the first substrate, said second BEOL dielectric layer covers an upper surface of said first BEOL dielectric layer, and said second substrate covers an upper surface of said second BEOL dielectric layer;
wherein, said groove is arranged in said second substrate of said second wafer, and said groove exposes parts of the upper surface of said second BEOL dielectric layer.

3. The image sensor as claimed in claim 1, wherein the upper surface of said second wafer is also covered with a first dielectric layer, and said first dielectric layer locates between said second wafer and said second dielectric layer.

4. The image sensor as claimed in claim 2, wherein a first metal layer are arranged in said first BEOL dielectric layer and said second BEOL dielectric layer respectively, and the two first metal layers contact with each other accurately;
wherein, said second BEOL dielectric layer is also provided with a second metal layer, and said second metal layer connects to said lead.

5. A preparation method of image sensor having an embedded color filter, comprising:
Step S1: proving a bonded wafer, said bonded wafer including a first wafer and a second wafer bonded above the first wafer; a groove being provided at top of said second wafer, and a lead having an opening on its top being provided in the groove;
Step S2: depositing a second dielectric layer to cover said second wafer and said lead and to fill said groove;
Step S3: performing a planarization process to said second dielectric layer, and then preparing a number of equidistant metal insulated gates on an upper surface of said second dielectric layer apart from top of the groove;
Step S4: embedding a color filter between each two adjacent metal insulated gates, and tops of the color filters being flush with those of the metal insulated gates, then removing parts of said second dielectric layer to expose the opening at the top of the lead.

6. The method as claimed in claim 5, wherein said first wafer includes a first substrate and a first BEOL dielectric layer, and said second wafer includes a second substrate and a second BEOL dielectric layer;
said first BEOL dielectric layer covers an upper surface of the first substrate, said second BEOL dielectric layer covers an upper surface of said first BEOL dielectric layer, and said second substrate covers an upper surface of said second BEOL dielectric layer;
wherein, said groove is arranged in said second substrate of said second wafer, and said groove exposes parts of the upper surface of said second BEOL dielectric layer.

7. The method as claimed in claim 6, wherein a first metal layer is provided in said first BEOL dielectric layer and said second BEOL dielectric layer respectively, and the two first metal layers contact with each other accurately;
wherein, said second BEOL dielectric layer is also provided with a second metal layer, and said second metal layer connects to said lead.

8. The method as claimed in claim 5, wherein in step S2, a first dielectric layer is provided between said second wafer and said second dielectric layer;
said first dielectric layer covers the upper surface of said second wafer and a bottom and side walls of the groove.

9. The method as claimed in claim 5, wherein material of said second dielectric layer is silicon oxide.
